(19) United States
(12) Patent Application Publication
(10) Pub. No.: US 2019/0267215 A1
(43) Pub. Date: Aug. 29, 2019

(54) METHOD FOR MANUFACTURING AN ANNULAR THIN FILM OF SYNTHETIC MATERIAL AND DEVICE FOR CARRYING OUT SAID METHOD

(71) Applicant: NEOCOAT SA, La Chaux-de-Fonds (CH)

(72) Inventors: David Rats, Neuchâtel (CH); Medhi Naamoun, Neuchâtel (CH); Christophe Provent, Cessy (FR)

(73) Assignee: NEOCOAT SA, La Chaux-de-Fonds (CH)

(21) Appl. No.: 16/320,439

(22) PCT Filed: Jul. 18, 2017
(86) PCT No.: PCT/EP2017/068158

§ 371 Date: Jan. 24, 2019

(30) Foreign Application Priority Data
Jul. 28, 2016 (EP) 16181774.7

(51) Int. Cl. H01J 37/32; C23C 16/27; C23C 16/511; C23C 16/458

(52) U.S. Cl. CPC H01J 37/32284; C23C 16/274; C23C 16/4583; H01J 37/32458; H01J 37/32211; C23C 16/511

(57) ABSTRACT

Methods and reactors are disclosed for producing synthetic material on a substrate by microwave plasma activated chemical vapor deposition. The method comprises the step of providing a microwave plasma reactor configured to provide a plasma having a toroidal shape. The reactor comprises a resonant cavity and a substrate holder arranged to hold, preferably, an annular shaped substrate or a plurality of substrates arranged in an annular configuration.

### FIELD OF INVENTION

The present invention relates to a method to manufacture thin film annular hard materials and also to a microwave plasma generator for manufacturing thin films of hard materials, such as synthetic diamond and related materials.

### BACKGROUND OF INVENTION

Diamond films possess a number of outstanding physical properties including extreme hardness, high thermal conductivity and wide-band optical transmission. This makes diamond in particular attractive for a number of applications.

Synthesis of thin films of hard materials such as diamond using chemical vapor deposition (CVD) techniques is well known and described in for example the Journal of Physics: Condensed matter, 21, 36 (2009) which gives an overview of diamond related technologies. An overview of CVD diamond deposition techniques and materials may be found in: J. E. Butler et al., “Understanding the chemical vapor deposition of diamond: recent progress”, Journal of Physics; Condensed Matter, Vol. 21, nr.36, 36422, (2009).

The deposition of polycrystalline diamond obtained with CVD technique is based on the principle of decomposing a gas mixture comprising hydrogen and a carbon precursor. The activation in the gas phase is performed either by Hot Filament Chemical Vapor Deposition (HFCVD) or by means of a Microwave Plasma (Microwave Plasma Chemical Vapor Deposition, or MPCVD) or DC Arc Plasma.

Microwave plasma chemical vapor deposition (MPCVD) techniques present several advantages such as: no contamination from filaments, high atomic hydrogen concentration that allows obtaining well controlled microstructures and a high quality of the deposited diamond films.

In the last 20 years several types of MPCVD reactors have been proposed such as ones based on a quartz tube, a quartz bell jar and having a cylindrical, or ellipsoidal or non-cylindrical shaped cavity of the reactor.

All MPCVD reactors are designed by choosing at least a resonance mode, a coupling system, a dielectric element and the dimension of the cavity. Reactors of prior art are all designed to coat disc shaped surfaces. For example Document US 20140230729 A1 describes a microwave plasma reactor for manufacturing synthetic diamond. The reactor described in US 20140230729 A1 uses a TM₀₁₁ resonant mode and provides a spherical shaped plasma which allows coating the full surface of a disc with a thin film diamond layer. As the plasma in the reactor described in US 20140230729 A1 has a spherical shape it does not allow to deposit other shapes than a disc like shape deposition.

On the other hand, HFCVD techniques allow depositing on various large size substrates but the required thickness of the diamond to be deposited is for most applications 20-100 μm. The growth rate of HFCVD techniques is about 0.15-0.5 μm/h, which is absolutely not acceptable for large capacity production of diamond thin films which have a thickness of tens of microns. With a single reactor it would take more than a week to realize some wafers having a diamond thickness of 20-100 μm.

There is a growing demand for processes and reactors that would allow realizing 20-100 μm thick diamond films on surfaces such as silicon carbide that have an annular shape and which have an exterior diameter of 300-400 mm. One application is for example for rotary seals for circulation pumps in industrial machines. Another application is focus rings in semiconductor etching machines. Due to the highly reactive environment of such machines existing rings are rapidly damaged by the reactive gases.

None of the available reactors or methods allows realizing in a cost effective way films of diamond having a thickness of about 20-100 μm on an annular shaped substrate having an outside diameter of more than 300 mm. Existing MPCVD reactors are limited to diameters of about 150 mm and the deposition by HFCVD reactors is too slow. None of the methods or devices of prior art are capable of realizing an annular shaped synthetic diamond film in a cost effective industrial way.

### SUMMARY OF THE INVENTION

The object of the invention is to provide a method to produce a toroidal plasma to realize an annular shaped deposition of material on a substrate. The invention relates also to a new microwave plasma reactor arranged to produce the toroidal shaped plasma.

More precisely the invention is achieved by a method for producing synthetic material on a substrate by microwave plasma activated chemical vapor deposition, comprising the steps of:
providing a microwave plasma reactor comprising a plasma enclosure defining a resonant cavity having a central axis, a substrate holder therein and a microwave delivery system,
   said plasma enclosure comprising a plasma chamber cover adapted to said top plate comprising, to the side opposite to said base plate, a plasma chamber ceiling defining the shape of said resonant cavity to the side opposite to said base plate,
   said substrate holder being arranged to hold a substrate or a plurality of substrates, said substrate holder facing said plasma chamber ceiling,
   said microwave delivery system comprising a microwave generator configured to generate microwaves at a frequency f, and comprising a microwave coupling system connecting said microwave generator to said resonant cavity by an entry of said plasma enclosure;
placing a substrate having a growth area, or a plurality of substrates, on said substrate holder;
introducing process gases into said resonant cavity, the process gases comprising at least a precursor gas and/or a reactive gas; and
generating microwaves into the resonant cavity and activate the process gases so as to form a plasma having a toroidal shape aligned and proximate to said substrate, said plasma having annular cross sections parallel to said substrate, whereupon at least one ring of synthetic material is grown over said growth area.

In an embodiment the method comprises a step of a linear or rotational displacement of the substrate holder relative to the toroidal shaped plasma.

In an embodiment the substrate is a single substrate or a plurality of substrates arranged in an annular arrangement on said substrate holder.

In an embodiment the plasma chamber ceiling has, in all planes comprising said central axis and to each side of said central axis, a cross section defined by a polynomial curve.

In an embodiment said curve is a portion of a parabola.

In an embodiment said curve is a portion of an ellipse.

In an embodiment the plasma chamber ceiling has, in all planes comprising said central axis and to each side of said central axis, a cross section defined by at least two different curves.

In an embodiment the resonant cavity is configured to support a TM resonant mode at said frequency f so that said resonant mode provides a plasma having a toroidal shape.

In an embodiment said resonant mode is a TM₀ₘₙ resonant mode.

In an embodiment said TM₀ₘₙ mode is a TM₀₁₁ mode.

In an embodiment the process gas comprises hydrogen (H) and carbon (C) sources.

In an embodiment the process gas may be chosen among CH₄, CO₂, C₂H₂, SiH₄, H₂, O₂, B₂H₆, CHF₃, SF₆, trimethyl borate (C₃H₉BO₃), N₂, Ar, fluorinated derivatives, phosphorous derivatives, chlorinated derivatives, sulfides derivatives, boron derivatives or a combination of them.

In an embodiment the material of the substrate is made of any material covered with a thin layer of another material chosen among Si, SiC, Si₃N₄, silicon derivatives, CB, CN, B₄C refractory metals and their derivatives, titanium and titanium-based alloys, cemented carbides, ceramics, oxides such as fused silica or alumina, carbon derivatives, carbide derived-carbon and carbon allotropes such as diamond, graphite, lonsdaleite, fullerite (C₆₀,C₅₄₀,C₇₀), amorphous carbon, and single and multi-walled carbon nanotube, carbyne, graphene or a combination of them.

In an embodiment the growth rate of the deposited synthetic material, defined as the deposited thickness per hour, is greater than 0.1 μm/h, preferably greater than 1 μm/h.

In an embodiment the reactor operates at a microwave frequency fin the range of 350 MHz to 500 MHz, or between 800 MHz and 1000 MHz, or between 2300 MHz and 2600 MHz, or between 5000 MHz and 6000 MHz.

In an embodiment a second substrate holder faces said substrate holder, the toroidal shaped plasma being formed between said first and second substrate holder, said first and second substrate holder being each arranged to hold a substrate to opposite sides of said plasma.

The invention is also achieved by a microwave plasma reactor for manufacturing synthetic material via chemical vapor deposition, the microwave plasma reactor comprising:
a plasma enclosure comprising a base plate, a top plate and a side wall extending from said base plate to said top plate defining a resonance cavity having a central axis, for supporting a TM microwave resonance mode;
a microwave delivery system comprising a microwave generator configured to generate microwaves at a frequency f;
a microwave coupling system arranged to couple microwaves from said generator into the resonance cavity;
a gas flow system, comprising at least one gas inlet for feeding process gases into the resonance cavity and at least one gas outlet for removing process gases therefrom;
a substrate holder defining an area to adapt a substrate;
at least one dielectric element,
wherein:
said plasma enclosure comprises a plasma chamber cover comprising, to the side opposite to said base plate, a plasma chamber ceiling defining the shape of the plasma resonance cavity to the side opposite to said base plate, so as to confine, in operation, a plasma having a toroidal shape;
said microwave coupling system comprises a coaxial guide connecting said microwave generator to an entry of said plasma enclosure;
said substrate holder is arranged to hold a substrate which can be a ring, a disc, a plate, or a plurality of substrates, preferably arranged in an annular arrangement, said substrate holder facing said plasma chamber ceiling.

In an embodiment, the plasma chamber ceiling has, in all planes comprising said central axis and to each side of said central axis, a cross section defined by a polynomial curve.

In an embodiment, said curve is a portion of a parabola.

In an embodiment, said curve is a portion of an ellipse.

In an embodiment the plasma chamber ceiling has, in all planes comprising said central axis and to each side of said central axis, a cross section defined by at least two different curves.

In an embodiment, at least one of said curves is a portion of a straight line.

In an embodiment, said plasma chamber ceiling has a primary symmetry axis parallel or coincident to said central axis.

In an embodiment, said gas inlet is a ring shaped opening having a symmetry center intersecting with said central axis.

In an embodiment, said gas inlet comprises a plurality of concentric ring shaped openings having each said central axis as symmetry axis.

In an embodiment, said gas inlet is a single gas inlet or a plurality of gas inlets having a symmetry center intersecting with said central axis.

In an embodiment, said plasma chamber cover comprises at least two concentric arrays of gas inlets, each concentric array having said central axis as symmetry axis.

In an embodiment, at least one of said gas inlets intersect with a virtual axis perpendicular to said growth area.

In an embodiment, said resonance cavity is configured to support at least one resonant TM mode between the base plate and said plasma cover ceiling, at said frequency f, so that said resonant mode provides a plasma having a toroidal shape when the reactor is in operation.

In an embodiment, said resonant mode is a TM₀ₘₙ mode.

In an embodiment, said TM₀ₘₙ mode is a TM₀₁₁ mode.

In an embodiment, the plasma reactor is configured to operate at a microwave frequency f in the range of 350 MHz to 500 MHz, or between 800 MHz and 1000 MHz, or between 2300 MHz and 2600 MHz, or between 5000 MHz and 6000 MHz.

In an embodiment, said substrate holder is configured to allow a linear movement in a direction parallel or making an angle relative to said central axis.

In an embodiment, said substrate holder is configured to allow a rotational movement in horizontal and/or or vertical plane.

### BRIEF DESCRIPTION OF THE DRAWINGS

FIG. 1 shows a vertical cross-sectional view of a microwave plasma reactor in operation and configured to deposit annular shaped synthetic hard material using a chemical vapor deposition technique;

FIG. 2 shows a cross sectional view of a microwave plasma reactor in operation, in a plane of the torus of the plasma parallel to the substrate holder of the reactor;

FIG. 3 shows a vertical cross sectional view of yet another microwave plasma reactor configured to deposit an annular shaped thin film of hard material on two substrates, each substrate being located in front of a side of the plasma having a toroidal shape, using a chemical vapor deposition technique in accordance with an embodiment of the present invention;

FIGS. 4 to 7 show different embodiments of plasma enclosures and resonant cavities;

FIG. 8 shows a top view of a plasma enclosure;

FIG. 9 shows a side view of a plasma enclosure and a coaxial guide;

FIG. 10 illustrates a plurality of ring shaped gas entries;

FIG. 11 illustrates concentric arrangements of gas entries

FIGS. 12-14 illustrate different configurations of a plasma reactor comprising two parts linked by a rotation axis.

FIG. 15 illustrates a perspective view of a plasma reactor comprising two parts that may be opened by rotation of two parts having a common vertical rotation axis.

### DETAILED DESCRIPTION OF CERTAIN EMBODIMENTS

FIG. 1 shows a microwave plasma reactor, also defined as plasma reactor or reactor, according to an embodiment of the present invention.

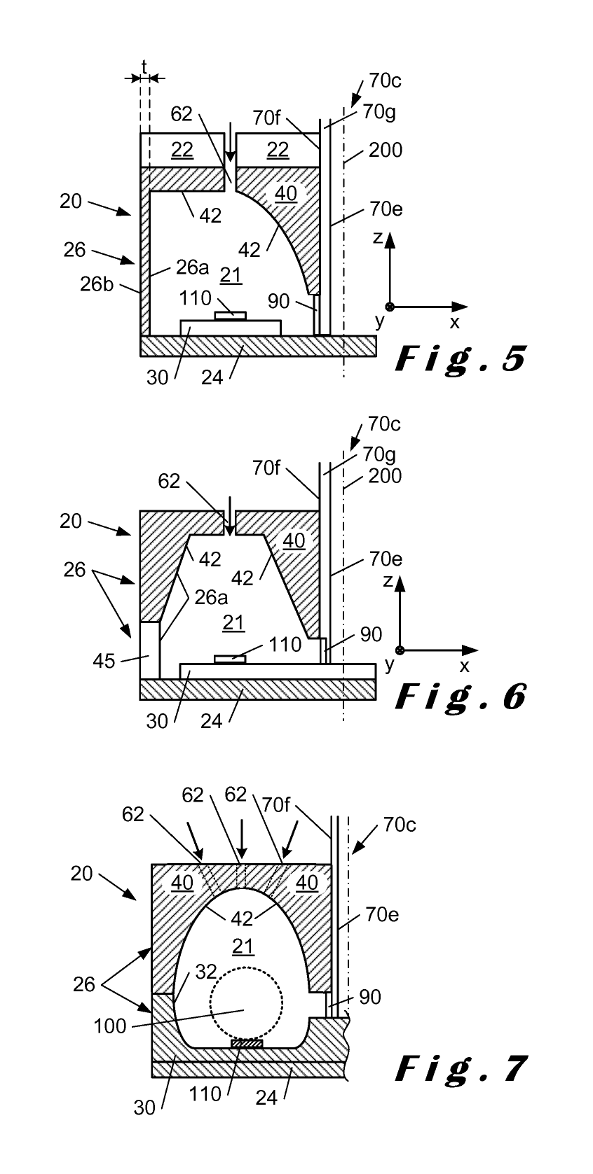

As can be seen by reference to FIG. 1, the microwave plasma reactor comprises the following elements:
a plasma enclosure 20, defining a resonant cavity 21, also defined as plasma chamber comprising at least (1-6):
   1. a top plate 22 having a top plate center 22a;
   2. a bottom plate, defined as base 24 plate having a reactor bottom surface 25, having a base plate center 25a. The virtual line comprising said centers 22a and 25a defines a central axis 200 of the reactor and defines the vertical z-axis in the plasma reactor. Perpendicular to said central axis 200 are defined horizontal planes being parallel to the substrate holder 30. Horizontal planes are defined by orthogonal x and y axis which are orthogonal to said z-axis;
   3. a plasma chamber cover 40 having a lower surface, to the side of said base plate 24, which is defined as the plasma chamber ceiling 42; As further described in detail said ceiling 42 may be flat or curved. The plasma chamber ceiling 42 may have different shapes, as further described, in function of the predetermined size and shape of the toroidal plasma that is produced by the reactor;
   4. a side wall 26 having a thickness t, illustrated in FIG. 5, and comprising an internal surface 26a, illustrated in FIGS. 5 and 6; it is understood that said thickness t must not necessarily be uniform and may vary as illustrated in the embodiment of FIG. 6 and FIG. 7;
   5. at least one dielectric element 90, having at least one internal face 90a oriented to the side of the resonant cavity 21 and being arranged to transmit microwaves to the resonance cavity 21;
   6. a substrate holder 30, disposed in the resonant cavity 21, for holding a substrate 110 having a growth surface 110a;
a microwave delivery system 70 comprising a microwave generator 70a, also defined as microwave source or source, which is the energy source for forming, in operation of the reactor, a plasma 100 having a toroidal shape within the plasma chamber 20, the microwave generator 70a being connected to the resonant cavity 21 by microwave transmission means comprising a microwave coupling system 72 which comprises, as illustrated in FIG. 1, typically three parts: a microwave guide 70b, a coaxial cable 70c to provide microwave into the resonant cavity 21, and an antenna 70d arranged between microwave guide 70a and said coaxial cable 70c. This configuration is well known to the person skilled in the art and is not further describes here. Reference for this is made to the following publication: Silva et al. J. Phys.: Condens. Matter 21 (2009) 364202;
a gas reservoir 65 connected to a gas flow distribution system 60, comprising gas inlets 62, for feeding process gases into the resonant cavity 21;
a gas outlet system, which comprises a pump and gas outlets 52, to remove process gases from said resonant cavity 21;

It is understood that the plasma enclosure 20 comprises all the mechanical elements that define the resonant cavity 21 in which the plasma 100 is formed when the reactor is in operation. The plasma enclosure 20 comprises also at least one entry 23 through which microwaves are coupled into the resonant cavity. Different configurations are described further and are illustrated in the FIGS. 1 to 11. FIGS. 5-7 illustrate only a cross section to one side of said central axis 200. For reasons of clarity FIGS. 5-7 do not show the microwave delivery system completely, nor the gas outlets of the reactor.

It is understood that said side wall 26 is defined broadly, being a wall having a predetermined thickness t. Advantageously the wall 26 may be part, at least partially, of said plasma chamber cover 40, as for example illustrated in the embodiments of FIGS. 5-7. Also, in embodiments the side wall 26 may comprise different elements as illustrated in the embodiment of FIGS. 6 and 7.

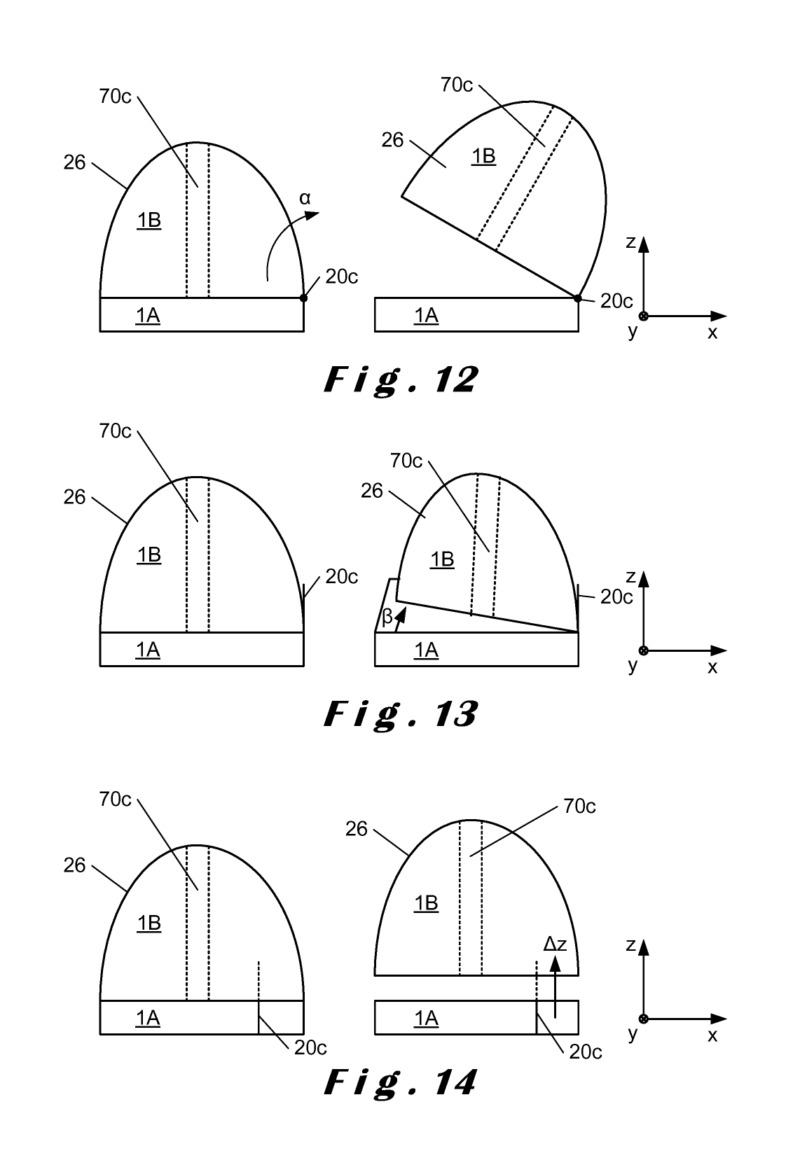

In its simplest configuration, illustrated in FIG. 1, the plasma enclosure 20 comprises preferably a cylindrical shaped wall 26 having a thickness t, a substantially flat plasma chamber cover 40 arranged to said top plate 22 to the side of said substrate holder 30, a substantially flat base plate 24 having a flat reactor bottom surface 25 and a dielectric element 90. The plasma enclosure 20 of said simplest configuration has a cylindrical shaped volume defining a resonant cavity 21 in which the toroidal plasma is formed when the reactor is in operation. In its simplest configuration, illustrated in FIG. 1, the resonant cavity 21 is formed by the volume defined by the internal surface of a wall 26, said reactor bottom surface 25, said plasma chamber ceiling 42 and said internal face 90a of the dielectric window. It is understood that in variants additional elements may be comprised in said plasma enclosure 20, such as for example an additional element 45 illustrated in the embodiment of FIG. 6. It is also understood that said plasma reactor bottom 25 must not be necessarily have a flat surface and that the base plate 24 may be realized by the assembly of different shaped elements. Advantageously, as illustrated in FIG. 7 the sample holder 30 may be configured so that the form of the lower portion of the resonant cavity 21 is determined, at least partially, by the internal surface 32 of the sample holder 30. In the embodiment of FIG. 7 the sample holder is adapted to a base plate 24 but in a variant the sample holder 30 may be configured as the base plate of the reactor. In a variant the reactor may be configured as shown in the embodiments of FIGS. 12-14, and discussed further, so that the plasma cover 40 and the sample holder 30 constitute two parts, respectively 1A and 1B, that may be rotated by a common rotation axis.

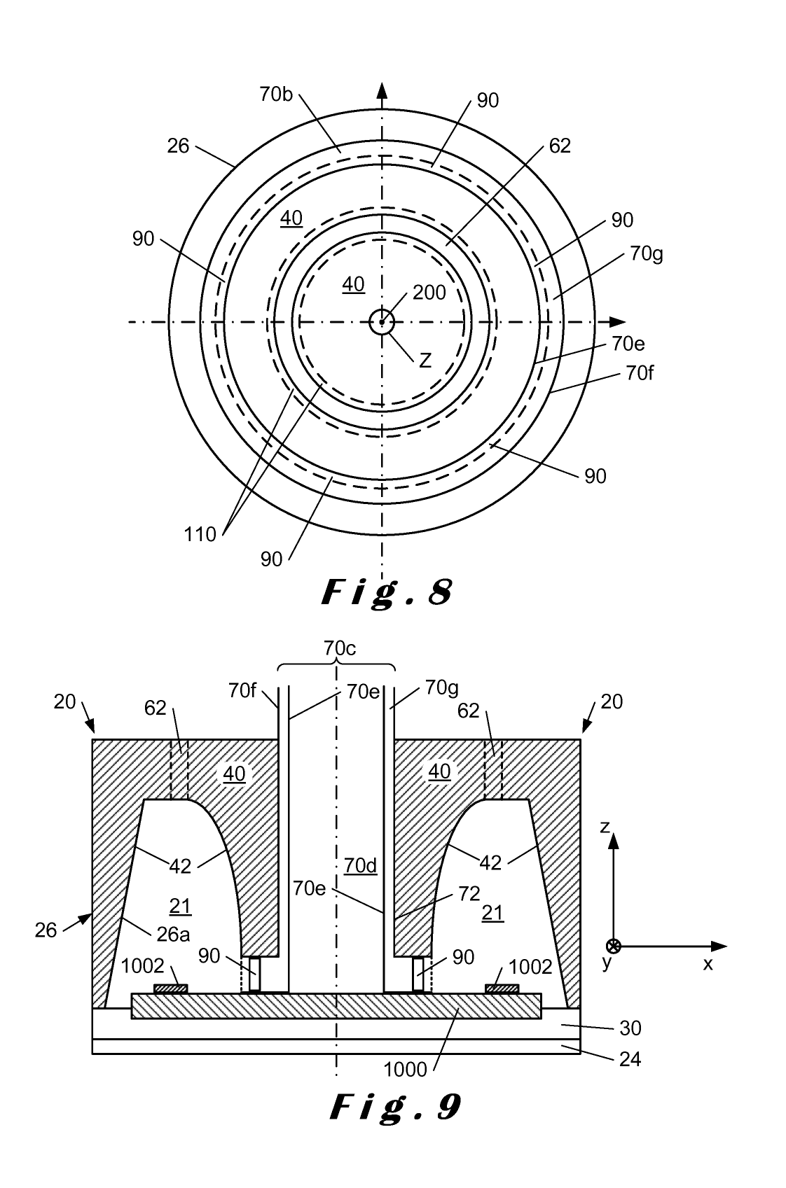

In a variant, the top plate 22 and the plasma chamber cover 40 may be made in a single piece as illustrated in FIG. 6 and FIG. 7. It is also understood that the wall 26, the base plate 24, the top plate 22, the dielectric window 90, the plasma chamber cover 40 may be realized by the assembly of different elements. These different elements may be realized by different materials or may comprise a coating, for example a coating adapted to protect the internal surfaces of the parts of the plasma enclosure 20. In a variant of said simplest configuration, microwaves may be coupled into the resonant cavity 21 in different arrangements. For example microwaves may be coupled through a dielectric window 90 positioned in the side wall 26, or in the base plate 24. FIG. 8 shows a top view of an embodiment comprising a cylindrical shaped dielectric element 90. In the embodiment of FIG. 7 the dielectric window 90 and the coaxial guide 70c have both the central axis as their symmetry axis, and both are arranged in or near the side wall 26 of the plasma enclosure 20.

Also, in variants, the process and reactive gases may be provided to the resonant cavity 21 through the base plate 24 or through the side wall 26, or both.

Also, in other variants, gas outlets may be arranged in another part of said plasma enclosure 20. It is also possible that the gas inlets 26 may be configured under the substrate holder 30, i.e. in the base plate 24.

As described further in detail, the gas inlets 62 may have different configurations and may be configured as a single ring, a single gas inlet or a plurality of gas inlets 62.

It has to be noted that, preferably, the center 30a of the substrate holder 30 and the center 112 of the substrate 110 are aligned on said central axis 200, but not necessarily so.

Advantageously the plasma reactor comprises a substrate thermostatic system, allowing cooling or heating, for controlling the temperature of a substrate 110. Different configurations of this thermo-regulated system are possible and are not represented in the Figures.

It is understood here that the wording plasma 100 means a plasma having a toroidal shape provided by the reactor when the reactor is in operation. The produced plasma by the reactor has a central plane 150, preferably parallel to the substrate holder 30, and has a plasma center 100a as illustrated in FIG. 1.

The wording “toroidal shape” comprises any shape of a plasma 100 which has a central portion 120, defined in a plane parallel to the substrate holder 30, which is not provided with plasma 100, such as a tubular shaped plasma which central cylindrical portion does not comprise plasma. The plasma torus 100 may have, in any plane perpendicular to the substrate holder 30, the shape of a ring torus or the shape of a horn torus or the shape of a spindle torus. The cross section of the plasma torus, in any plane perpendicular to the substrate holder, must not necessarily have a circular shape but may have an elliptical shape or a shape defined by a polynomial function.

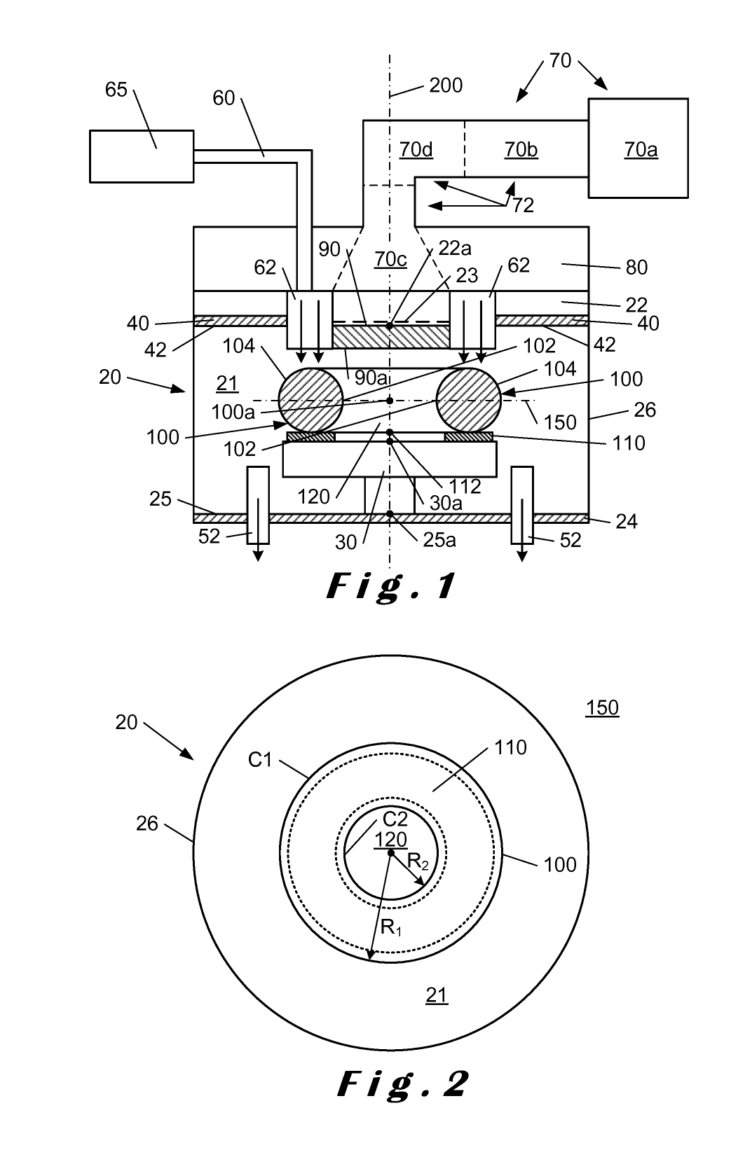

Preferably, the shape of the plasma in its central plane 150 is defined by two concentric circles C1 and C2 defining a major axis R1 and a minor axis R2 of the torus as illustrated in FIG. 2. The toroidal plasma 102 has an inner surface 102 to the side of said central axis and an outer surface 104 to the side opposite to said inner surface 102. Preferably the cross section of the outer 104 and inner 102 surface of the torus, defined in a plane comprising the central axis 200, are half circles, but not necessarily so. For example, the cross section of the outer 104 and inner 102 surface of the torus, defined in a plane comprising the central axis 200, may be defined by a portion of an ellipse.

The cross section of the plasma 100, defined in any plane parallel to said substrate holder 30 may have any shape, preferably a ring type shape but other shapes are possible such as a flattened ring. More precisely, the inner border 102 and the outer border 104, may each be defined by a polynomial function. Preferably the shape of the inner border 102 and the outer border 104 is a circle or an ellipse. The shape of the outer border 104 of any cross section of the plasma, defined in any plane parallel to said substrate holder 30, may be different to the shape of the inner border 102 of the plasma in said plane. For example, the outer plasma border 102 may have an elliptical shape and the inner plasma border 104 may be substantially circular in any plane parallel to the substrate holder 30.

In a preferred embodiment, the resonance cavity 21 is configured to have a shape which supports a resonant mode between the reactor base surface 25, the inner wall 26 and the plasma chamber ceiling 42 at a microwave frequency f, so that a plasma having a toroidal shape may be produced in the resonant cavity 21 and so that the toroidal plasma remains stable during the operation of the reactor.

In an embodiment the reactor operates at a microwave frequency fin the range of 350 MHz to 500 MHz, or between 800 MHz and 1000 MHz, or between 2300 MHz and 2600 MHz, or between 5000 MHz and 6000 MHz.

In an embodiment the ratio of the geometry of the plasma chamber of the microwave plasma reactor is chosen to provide and sustain a plasma having a stable toroidal shape during the operation of the reactor.

In an embodiment the plasma reactor has a cylindrically shaped cavity, but other shapes, for example a reactor cross section defined by a polynomial in any horizontal plane of the reactor are also possible.

In variants of the invention, different TM resonant modes may be used to provide a plasma having a toroidal shape.

In an embodiment said resonant mode is a TM₀ₘₙ mode.

In an embodiment said TM₀ₘₙ mode is a TM₀₁₁ mode.

The dielectric window 90 is preferably a disc shaped dielectric element and is arranged, in the basic configuration of FIG. 1, parallel to the top plate 22. The dielectric can also have an annular shape, a conical shape, a tubular shape or any other suitable shapes.

In variants, at least one of the center 112 of the substrate 110, the center 90a of the dielectric window 90, the center 30a of the substrate holder 30, is not located on said central axis 200.

In an embodiment, the resonant cavity 21 may be configured so that, when the reactor is in operation, the toroidal plasma 100 is decentered relative to said central axis 200 and/or the center 111 of a substrate 111 and/or the center 30a of the substrate holder 30, and/or the center 90a of the dielectric element, said decentering being understood as relative to a virtual vertical axis through the substrate center 112 and/or the center 30a of the substrate holder center 30,

In an embodiment, the substrate holder 30 may comprise a plurality of substrate holders arranged in an annular configuration facing said plasma when the reactor is in operation. Preferably the plurality of substrate holders are aligned symmetrically relative to said central axis 200. On at least one of said plurality of substrate holders a substrate 110 to be coated may be adapted.

More generally, the wording substrate holder 30 comprises any type of substrate holder 30 or plurality of substrate holders 30 that allow to adapt at least one object, defined as substrate 110, on a ring shaped surface portion of said substrate holder 30 being parallel and facing the toroidal plasma when the reactor is in operation. Advantageously the growth surface 110a may be the surface of a coated area of the substrate 110 layer. In a variant the substrate is a ring shaped substrate comprising a coating to the side where a layer has to be deposited by the reactor. For example the substrate may be a steel ring comprising a dielectric coating. In another example, the substrate may be a SiC ring comprising a graphene coating.

In a variant, a plurality of substrates 110, on which a layer has to be deposited by the reactor in operation, may be arranged on a single substrate holder 30 having a disc shape.

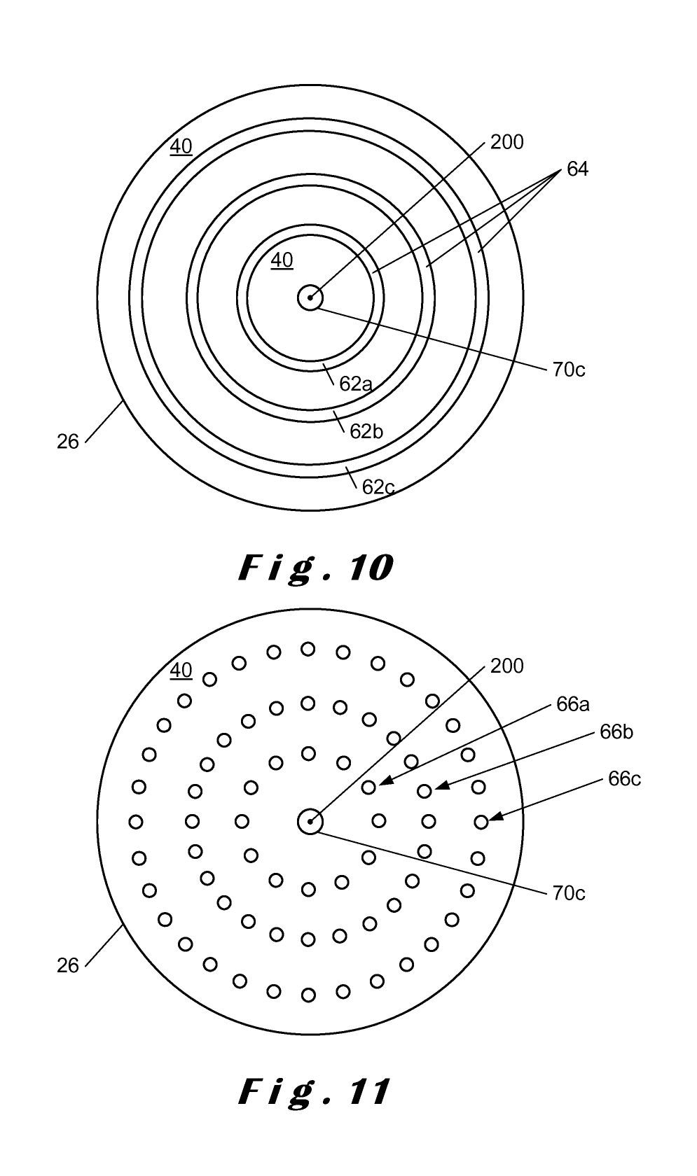

In embodiments the substrate holder 30 may be configured so that a wafer 1000 may be placed and/or fixed on the substrate holder 30, as illustrated in FIG. 9. FIG. 9 illustrates a ring shaped coating 1002 formed on a wafer substrate 1000.

In the embodiments of FIGS. 1 to 9 the gas inlets 62 are oriented parallel to said central axis 200.

In a variant the gas inlets 62 may have different orientations. In a variant a plurality of gas inlets 62 may be provided in the plasma reactor and each of said plurality of gas inlets 62 may have different orientations relative to said central axis 200.

In another variant, gas inlets 62 may be arranged and oriented in at least one horizontal plane of the plasma reactor.

In embodiments the gas inlets 62 may be a ring array 64 comprising concentric ring shaped gas inlets as illustrated in FIG. 10.

In a variant, illustrated in FIG. 11, the gas inlets 62 are arranged as a plurality of concentric arrays (66a, 66b, 66c) of gas inlets 62.

It is understood that the gas inlets 62 may have for example a cylindrical or a conical shape. It is also understood that not all the gas inlets 62 of the arrays of FIGS. 9 and 10 have the same shapes. For example, in the embodiment of FIG. 11 the gas inlets of the first array 66a may have a different geometry than the gas inlets of the second array 66b.

Similarly, the gas outlets 52 are preferably situated in the lower part of the plasma reactor as illustrated in FIG. 1. In a variant the gas outlets 52 may have a different orientation and may be arranged in the top plate 22 or also in the wall 26.

In a variant, a plurality of gas outlets 52 may be provided in the plasma reactor and each of said plurality of gas outlets 52 may have different orientations relative to said vertical axis 200. In a variant, gas outlets 52 may be arranged and oriented in a horizontal plane of the plasma reactor.

In an embodiment, the microwave delivery system 70 may has a particular configuration able to shape and maintain the toroidal shape of the plasma. The same holds for the dielectric window which may be configured to shape and/or stabilize the toroidal plasma. For example the microwave delivery system 70 may comprise a microwave guiding device which its extremity, positioned inside the entry 23 of the resonance cavity 21, has a particular shape that allows shaping and stabilizing the annular plasma when the reactor is in operation. Said particular shape of the extremity may be for example a spherical or a cylindrical or a tubular or a conical shape.

In embodiments illustrated in FIGS. 4 to 9 the microwave guiding device is a coaxial guide 70c comprising a tube having an inner wall 70e and an outer wall 70f, the inner portion 70g of the wall of the tube being arranged to guide the microwaves. The inner portion 70c of the microwave coaxial guide is preferably an empty portion surrounded by concentric walls, or may include internal tubes filled by gas and/or a cooling liquid such as water. In embodiments illustrated in FIGS. 4 to 9 the extremity of the coaxial guide 70c is positioned facing an entry 23 of the resonant cavity 21 and a ring shaped dielectric element 90 is positioned in said entry. In variants the dielectric element 90 may have a hexagonal shape having said central axis 200 as symmetry axis.

In an embodiment, additional conducting or dielectric elements may be positioned in the plasma reactor 20, for example to the side wall 26 of the plasma reactor. Said additional elements may serve to shape and stabilize the toroidal shaped plasma when the reactor is in operation. The plasma reactor has a cylindrical shape but this is not necessary so. The cross section of the plasma reactor in any horizontal plane may have any shape defined by a polynomial function.

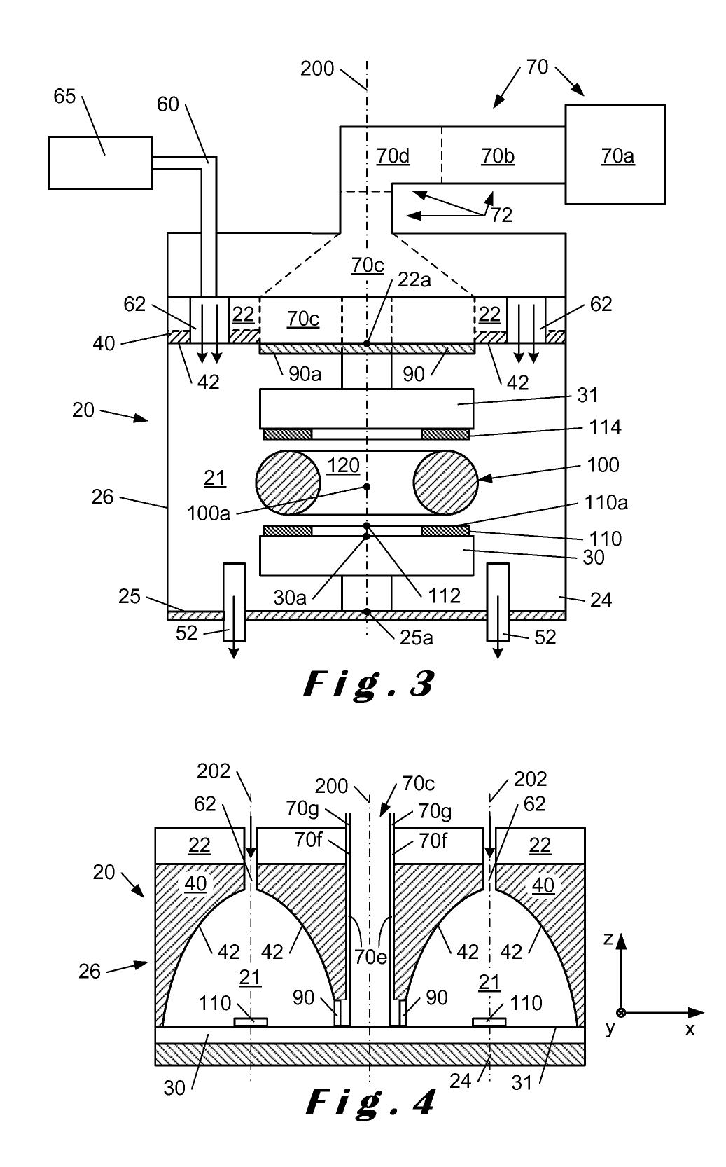

In an embodiment, the reactor is configured to coat, in operation, two substrates 110,114 each of the substrates being positioned and held to opposite sides of said plasma 100, as illustrated in FIG. 3. This may be realized for example by clamping each of the substrates 110,112 on a side of a substrate holder 30, 31. In this embodiment, not shown in a figure, the plasma is situated in between said lower and upper surface, said upper and lower portion being mechanically connected by a central element that passes through the central portion 120 of the plasma. This embodiment allows realizing the simultaneous coating of two ring shaped substrates 110, 111.

In an embodiment the reactor may be arranged to produce, in operation, at least two plasmas having a toroidal shape, each toroidal plasma having a different outer diameter and each plasma having the same symmetry center defined in a plane parallel to said substrate holder 30. This embodiment allows coating at least two ring shaped substrates having a different diameter.

In a variant said symmetry center of the at least two toroidal plasmas is different.

In variants the two toroidal plasmas may be concentric and situated in one plane or the two toroidal plasmas may be parallel.

It is understood also that the substrate holder 30 may be configured to adapt a plurality of substrates so that on each of said plurality of substrates an annular sector, i.e. having an arc shape, a hard material coating may be deposited by the reactor.

In a preferred embodiment the plasma chamber ceiling 42 has, in any plane comprising said central axis 200, and to both sides of said central axis 200, a cross section which has the shape of a curve defined by a polygon.

In an embodiment said curve is a portion of a parabola.

In an embodiment said curve is a portion of an ellipse.

In an embodiment, any cross section of the plasma chamber ceiling 42, in a plane comprising said central axis 200 and to each side of said central axis 200, is defined by a portion of at least two different curves.

In an embodiment at least one of said curves is a portion of a straight line.
In an embodiment said plasma chamber ceiling 42 has a primary symmetry axis parallel to said central axis 200.

In a variant said symmetry axis is collinear with said central axis 200.

In an embodiment, illustrated in FIG. 4, the portion of any cross section of said plasma chamber ceiling 42 with a plane comprising said central axis 200, to a side relative to said central axis 200, comprises a secondary symmetry axis 202 parallel to said central axis 200.

Advantageously said secondary symmetry axis 202 may intersect with said area 110a.

In embodiments, illustrated in FIGS. 12-14 the plasma reactor may comprise a first part (1A) and a second part (2B) linked by a common rotation axis 20c, 203. The configurations of FIGS. 12-14 allow to facilitate the insertion of a substrate 100 in the plasma reactor. Other configurations to open and close the plasma reactor may of course be considered and are not described here. For example a plasma reactor comprising a rectangular shaped side opening through which a substrate may be inserted.

FIGS. 12-14 illustrate closed and open positions of the plasma reactor.

In the embodiment of FIG. 12 the reactor is configured so that said two parts 1A, 1B may be rotated by an angle α around a horizontal axis 20c.

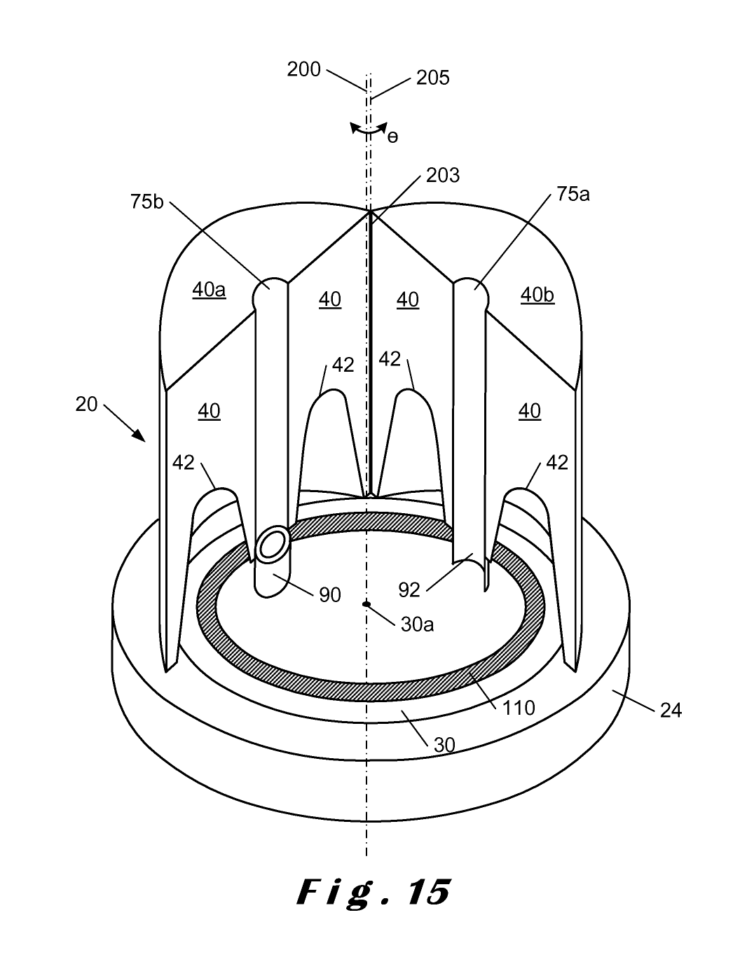

In the embodiment of FIG. 13 the reactor is configured so that said two parts 1A, 1B may be rotated by an angle β in a horizontal plane around a vertical axis 20c. The embodiment of FIG. 15 illustrates an example of a configuration of a plasma reactor comprising two parts 40a, 40b which can be rotated by an angle θ around a common axis 203 allowing said two parts 40a and 40b to move in a horizontal plane. In the embodiment of FIG. 15, the first part comprises first opening 75A and the second part 1B comprises a second opening. By closing the two parts 1A, 1B the two openings 75a, 75b form a central opening in which the microwave guide 70c may be arranged.

In the embodiment of FIG. 14 the reactor is configured so that said two parts 1A, 1B may be separated by a displacement Δz in the vertical direction.

In variants the plasma reactor is configured to allow a vertical movement of the substrate holder 30.

It is understood that in all the embodiments of the invention the deposition rate of the deposited synthetic material on a substrate, defined as the deposited thickness per hour, may be greater than 0.1 μm/h. In the case of the deposition of diamond the deposited thickness per hour, is typically greater than 0.1 μm/h.

The growth rate is typically between 0.1 μm/h to 50 μm/h and preferably between 1 μm/h to 10 μm/h.

The invention is also achieved by a method to realize an annular shaped thin film of a coating, which is preferably but not necessarily so, a hard coating, such as an annular diamond coating. Other typical examples are: a SiC coating, a protective layer coating or a very thin layer of a semiconductor material having a very high dopant concentration (such as delta-doped layer).

More precisely the invention provides a method for producing synthetic material on a substrate by microwave plasma activated chemical vapor deposition, comprising the steps of:
providing a microwave plasma reactor, as described before, comprising a resonant cavity 21 with a substrate holder 30 therein, said resonant cavity 21 being configured to produce a plasma having a toroidal shape, the substrate holder 30 being arranged to hold a substrate 110 or a plurality of substrates 110 arranged in an annular arrangement, said substrate holder 30 being parallel and facing said plasma, said reactor comprising a microwave generator 70 configured to generate microwaves at a frequency f;
introducing a substrate 110, or a plurality of substrates 110 arranged in a ring, into the plasma chamber of the reactor and adapting said substrate 110 or plurality of substrates 110 on said substrate holder 30. The substrate 110, or the plurality of substrates 110, may be placed on said substrate holder 30 without using fixing means or may be clamped to the substrate holder 30 or put in place to the substrate holder 30 by any other means, such as magnetic or electric means.
introducing at least one precursor and/or reactive gases into said resonant cavity 21, and
introducing microwaves into the resonant cavity 21 to activate the process gas and form said plasma having a toroidal shape aligned and proximate to said substrate 110 whereupon a ring of synthetic material is grown over the growth surface 110a of the substrate 110.

A precursor gas may be, but is not limited to, one of CH₄, CO₂, C₂H₂, and SiH₄ or a combination of them. Reactive gases may be, but not limited to, one of H₂, O₂, B₂H₆, CHF₃, SF₆, TMB, and N₂, or a combination of them.

In an embodiment the substrate is a ring shaped substrate 110. The substrate may also be a plate or a disc or may have any other shape, even a curved shape. The process steps as described above allow depositing a ring shaped diamond layer on said substrate 110.

In an embodiment of the process may comprise steps assuring that the shape of the plasma remains stable during the coating process.

It is generally understood that in variants, the process steps and/or parameters may be varied to modify the shape of the plasma during operation of the plasma. For example, during the coating process the dimension of the plasma in the vertical direction or in any horizontal plane may be varied. In a variant, the shape of the plasma may be varied during the coating process. For example the plasma may have a torus shape at the start of the coating process and have a flattened torus shape at the end of the coating process.

It is generally understood that in variants, the gas injection system may be varied to change the shape of the plasma during operation of the plasma. For example, during the coating process the dimension of the plasma in the vertical direction or in any horizontal plane may be varied. In a variant, the shape of the plasma may be varied during the coating process. For example the plasma may have a torus shape at the start of the coating process and have a flattened torus shape during the coating process. In another embodiment the orientation of the plasma relative to the substrate may be varied or modified by moving the substrate holder. The substrate holder may be moved during the plasma deposition process in the vertical direction but also in a horizontal plane according to a linear displacement or a rotation. The substrate may also be rotated during the deposition process relative to any virtual rotation axis that is parallel to the base plate 24. It is also understood that the reactor may be configured so that the deposited layer is only a portion of a ring. For example, means may be provided so that only on half of the surface of a ring shaped substrate a coating is deposited. Said means may for example be a mask or a resin, or a combination of both, that avoids the deposition of a layer on a portion of the substrate 110. It is understood that in variants electromagnetic and/or mechanical means may be provided, preferably between said plasma 100 and said substrate 110, so as to deposit on said substrate 110 a ring shaped deposition of a plurality of layers. It is also understood that means may be provided so that the deposited layer is a ring shaped layer but does not cover the whole surface 110a of the substrate 110.

In an embodiment the parameters of the deposition process may be adapted so that the width of the deposited ring of material is smaller than the width of the annular substrate 110, said width begin defined respectively in the plane of said hard material and said substrate 110.

In an embodiment the substrate 110 has an annular shape and the process is adapted so that the width of the annulus of the torus of the plasma, defined in the central plane 150, is greater than the width of the annulus of the substrate 110. This may be realized by adapting the injection of the gases, the working pressure and/or by the addition of specific gases during the deposition process.

In a variant the substrate 110 has an annular shape and the width of the deposited annulus of the torus of the plasma, defined in the central plane 150, is smaller than the width w of the annulus of the substrate.

In an embodiment, the material of the substrate 110, on which an annular shaped diamond thin film has to be deposited, is chosen among diamond (C), Silicon (Si), SiC, Si₃N₄, silicone derivatives, CB, CN, B₄C, refractory metals and their derivatives, titanium and titanium-based alloys, cemented carbides, ceramics, oxides such as fused silica or alumina or a combination of them. Other materials that can be deposited are carbon derivatives, carbide derived-carbon and all carbon allotropes such as but not limited to: diamond, graphite, lonsdaleite, fullerite (C₆₀, C₅₄₀, C₇₀), amorphous carbon, and single and multi-walled carbon nanotube, carbyne, graphene or a combination of them.

In an embodiment the external diameter of the deposited annular substrate is greater than 100 mm.

In an embodiment the deposition rate of the deposited synthetic material, defined as the deposited thickness per hour, is greater than 0.1 μm/h.

In an embodiment of the method the reactor operates at a microwave frequency f in the range of 350 MHz to 500 MHz, or between 800 MHz and 1000 MHz, or between 2300 MHz and 2600 MHz, or between 5000 MHz and 6000 MHz.

It is understood that the reactor may comprise further parts or configurations or process steps that allow modifying the shape or dimensions of the deposited thin film of the deposited material. For example the reactor may be configured, so that after the deposition of the hard annular coating, a portion of the deposited thin film of hard material may be etched. This may allow for example to manufacture an annular shaped thin film of diamond having annular sectors that have different thicknesses. Another example is to provide means in the reactor so that apertures may be realized in the annular deposited thin film of hard material.

Also, additional coating means may be provided in the reactor to enable to coat the deposited annular thin film of hard material with a further thin film, for example the deposition of an anti-reflection layer, a buffer layer or a delta-doped layer.

1. A method for producing synthetic material on a substrate by microwave plasma activated chemical vapor deposition, comprising the steps of:
providing a microwave plasma reactor comprising a plasma enclosure defining a resonant cavity having a central axis, a substrate holder therein and a microwave delivery system,
said plasma enclosure comprising a plasma chamber cover adapted to said top plate comprising, to the side opposite to said base plate, a plasma chamber ceiling defining the shape of said resonant cavity to the side opposite to said base plate,
said substrate holder being arranged to hold a substrate or a plurality of substrates, said substrate holder facing said plasma chamber ceiling,
said microwave delivery system comprising a microwave generator configured to generate microwaves at a frequency f, and comprising a microwave coupling system connecting said microwave generator to said resonant cavity by an entry of said plasma enclosure;
placing a substrate having a growth area, or a plurality of substrates, on said substrate holder;
introducing process gases into said resonant cavity, the process gases comprising at least a precursor gas and/or a reactive gas; and
generating microwaves into the resonant cavity and activate the process gases so as to form a plasma having a toroidal shape aligned and proximate to said substrate, said plasma having annular cross sections parallel to said substrate, whereupon at least one ring of synthetic material is grown over said growth area.

2. The method according to claim 1 wherein the shape of the substrate is a ring.

3. The method according to claim 1 wherein the substrate is a single substrate or a plurality of substrates arranged in an annular arrangement on said substrate holder.

4. The method according to claim 1 wherein, the plasma chamber ceiling has, in all planes comprising said central axis and to each side of said central axis, a cross section defined by a polynomial curve.

5. The method according to claim 4 wherein said curve is a portion of a parabola.

6. The method according to claim 4 wherein said curve is a portion of an ellipse.

7. The method according to claim 1, wherein the plasma chamber ceiling has, in all planes comprising said central axis and to each side of said central axis, a cross section defined by at least two different curves.

8. The method according to claim 1, wherein the resonant cavity is configured to support a TM resonant mode at said frequency f so that said resonant mode provides a plasma having a toroidal shape.

9. The method according to claim 8 wherein said resonant mode is a TM0mn resonant mode.

10. The method according to claim 9 wherein said TM0mn mode is a TM011 mode.

11. The method according to claim 1, wherein the process gas comprises hydrogen (H) and carbon (C).

12. The method according to claim 1, wherein the process gas may be chosen among CH₄, CO₂, C₂H₂, SiH₄, H₂, O₂, B₂H₆, CHF₃, SF₆, TMB, N₂, Ar, fluorinated derivatives, phosphorous derivatives, chlorinated derivatives, sulfide derivatives, boron derivatives or a combination of them.

13. The method according to claim 1, wherein the material of the substrate is made of any material covered with a thin layer of another material chosen among Si, SiC, Si₃N₄, silicon derivatives, CB, CN, B₄C refractory metals and their derivatives, titanium and titanium-based alloys, cemented carbides, ceramics, oxides such as fused silica or alumina, carbon derivatives, carbide derived-carbon and all carbon allotropes such as diamond, graphite, lonsdaleite, fullerite (C₆₀, C₅₄₀, C₇₀) amorphous carbon, and single and multi-walled carbon nanotube, carbyne, graphene or a combination of them.

14. The method according to claim 1, wherein the growth rate of the deposited synthetic material, defined as the deposited thickness per hour, is greater than 0.1 μm/h.

15. The method according to claim 1, wherein the reactor operates at a microwave frequency fin the range of 350 MHz to 500 MHz, or between 800 MHz and 1000 MHz, or between 2300 MHz and 2600 MHz, or between 5000 MHz and 6000 MHz.

16. The method according to claim 1, wherein a second substrate holder faces said substrate holder, the toroidal shaped plasma being formed between said first and second substrate holder, said first and second substrate holder being each arranged to hold a substrate to opposite sides of said plasma.

17. The method according to claim 1 comprising a step of a linear or rotational displacement of the substrate holder relative to the toroidal shaped plasma.

18. A microwave plasma reactor for manufacturing synthetic material via chemical vapor deposition, the microwave plasma reactor comprising:
a plasma enclosure comprising a base plate, a top plate and a side wall extending from said base plate to said top plate defining a resonance cavity, having a central axis, for supporting a TM microwave resonance mode;
a microwave delivery system comprising a microwave generator configured to generate microwaves at a frequency f;
a microwave coupling system arranged to couple microwaves from said generator into the resonance cavity;
a gas flow system, comprising at least one gas inlet for feeding process gases into the resonance cavity and at least one gas outlet for removing process gases therefrom;
a substrate holder defining an area to adapt a substrate;
at least one dielectric element,
wherein:
said plasma enclosure comprises a plasma chamber cover comprising, to the side opposite to said base plate, a plasma chamber ceiling defining the shape of the plasma resonance cavity to the side opposite to said base plate, so as to confine, in operation, a plasma having a toroidal shape;
said microwave coupling system comprises a coaxial guide connecting said microwave generator to an entry of said plasma enclosure;
said substrate holder is arranged to hold a substrate which can be a ring, a disc, a plate, a single substrate or a plurality of substrates, preferably arranged in an annular arrangement, said substrate holder facing said plasma chamber ceiling.

19. The microwave plasma reactor according to claim 18 wherein, the plasma chamber ceiling has, in all planes comprising said central axis and to each side of said central axis, a cross section defined by a polynomial curve.

20. The microwave plasma reactor according to claim 19 wherein said curve is a portion of a parabola.

21. The microwave plasma reactor according to claim 19 wherein said curve is a portion of an ellipse.

22. The microwave plasma reactor according to claim 18 wherein the plasma chamber ceiling has, in all planes comprising said central axis and to each side of said central axis, a cross section defined by at least two different curves.

23. The microwave plasma reactor according to claim 22 wherein at least one of said curves is a portion of a straight line.

24. The microwave plasma reactor according to claim 18, wherein said plasma chamber ceiling has a primary symmetry axis parallel or coincident to said central axis.

25. The microwave plasma reactor according to claim 18, wherein said gas inlet is a ring shaped opening having a symmetry center intersecting with said central axis.

26. The microwave plasma reactor according to claim 18, wherein said gas inlet comprises a plurality of concentric ring shaped openings having each said central axis as symmetry axis.

27. The microwave plasma reactor according to claim 18, wherein said gas inlet is a single gas inlet or a plurality of gas inlets having a symmetry center intersecting with said central axis.

28. The microwave plasma reactor according to claim 18, wherein said plasma chamber cover comprises at least two concentric arrays of gas inlets, each concentric array having said central axis as symmetry axis.

29. The microwave plasma reactor according to claim 18, wherein at least one of said gas inlets intersects with a virtual axis perpendicular to said growth area.

30. The microwave plasma reactor according to claim 18, wherein said resonance cavity is configured to support at least one resonant TM mode between the base plate and said plasma cover ceiling, at said frequency f, so that said resonant mode provides an plasma having a toroidal shape when the reactor is in operation.

31. The microwave plasma reactor according to claim 30 wherein said resonant mode is a TM₀ₘₙ mode.

32. The microwave plasma reactor according to claim 31 wherein said TM₀ₘₙ mode is a TM₀₁₁ mode.

33. The microwave plasma reactor according to claim 18, wherein the plasma reactor is configured to operate at a microwave frequency f in the range of 350 MHz to 500 MHz, or between 800 MHz and 1000 MHz, or between 2300 MHz and 2600 MHz, or between 5000 MHz and 6000 MHz.

34. The microwave plasma reactor according to claim 18, wherein said substrate holder is configured to allow a linear movement in a direction parallel or making an angle relative to said central axis.

35. The microwave plasma reactor according to claim 18, wherein said substrate holder is configured to allow a rotational movement in a horizontal and/or vertical plane.
